(19) United States
(12) Patent Application Publication
(10) Pub. No.: US 2003/0053568 A1
(43) Pub. Date: Mar. 20, 2003

(54) State metric rescaling for Viterbi decoding

(76) Inventors: Farshid Rafiee Rad, Minneapolis, MN (US); Barrett J. Brickner, Savage, MN (US)

Correspondence Address: SHUMAKER & SIEFFERT, P. A., 8425 SEASONS PARKWAY, SUITE 105, ST. PAUL, MN, 55125, US

(21) Appl. No.: 10/237,550

(22) Filed: Sep. 6, 2002

Related U.S. Application Data
(60) Provisional application No. 60/317,904, filed on Sep. 8, 2001.

(51) Int. Cl. H03D 1/00; H04L 27/06; H03M 13/03

(52) U.S. Cl. 375/341; 714/795

(57) ABSTRACT

A decoder rescales state metric values to avoid overflow by resetting a bit in state metric registers that store the state metric values for each state. For example, the decoder may monitor a most significant bit (MSB) of the state metric registers to determine when the state metric values for all of the states exceed a threshold value. Upon exceeding the threshold value, the decoder may rescale the state metric values to avoid overflow. For instance, when the state metric values exceed the threshold value, the MSBs of the state metric registers may be reset. Resetting the MSBs is equivalent to subtracting half of the maximum value of the state metric register. The resealing technique can prevent state metric value overflow while offering reduced complexity and reduced latency.

This application claims priority from U.S. Provisional Application Serial No. 60/317,904, filed Sep. 8, 2001, the entire content of which is incorporated herein by reference.

### TECHNICAL FIELD

The invention relates to wireless communications and, more particularly, to techniques for decoding wireless signals communicated in a wireless communication system.

### BACKGROUND

Wireless communication involves transmission of encoded information on a modulated radio frequency (RF) carrier signal. A wireless transceiver includes an RF antenna that receives and transmits wireless signals. The wireless transceiver converts received RF signals to a baseband frequency for demodulation, and upconverts baseband signals to RF for transmission. In a multi-carrier wireless communication system, such as an orthogonal frequency division multiplexing (OFDM) system, the wireless transceiver demodulates the communication signal using digital signal processing techniques, such as fast Fourier transform (FFT) processing, and decodes the information carried by the demodulated signal.

Encoding techniques involve mapping a finite number of bits to a symbol to encode information in the wireless signal. To decode the information, the receiver demaps the symbol and applies a convolutional decoder such as a Viterbi decoder. The Viterbi decoder uses an algorithm to efficiently perform maximum-likelihood decoding of convolutional codes. In particular, the Viterbi algorithm computes state metric values using a trellis, and decodes the symbols using the state with the smallest state metric value.

State metric values have a maximum allowable value after which the state metric experiences overflow. State metric overflow can have a significant impact on overall decoding performance. In particular, upon overflow, the largest state metric value suddenly becomes the smallest state metric value, as a result of overflow “wrap-around.” Consequently, state metric overflow changes the movement direction in the trellis substantially.

To prevent the overflow problem, the number of state metric quantization bits may be increased such that the decoder accommodates the maximum possible state metric value. As the state metric values grow, however, the number of bits needed to combat overflow can become practically unrealizable.

Another proposed solution to address overflow of state metrics is based on two's complement arithmetic. In this case, the state metric values are represented in two's complement format, and comparisons are made using the two's complement representations. This approach automatically accommodates overflow, but tends to increase the range of individual metric values, which may require one or more additional state metric quantization bits.

A third approach to addressing overflow of state metrics involves the use of a rescaling mechanism. For example, a minimum state metric value may be periodically subtracted from each of the state metrics to prevent overflow. However, finding the minimum state metric value among many states can be computationally intensive. Further, in a fully parallel Viterbi decoder, resealing implementation generally requires as many subtractors as states in the trellis.

### SUMMARY

In general, the invention is directed to techniques for resealing state metric values in a decoder to prevent state metric overflow. The techniques may be useful, for example, in a parallel Viterbi decoder having a relatively large number of states. The techniques may involve tracking state metric values for each decoder state, and rescaling the state metric values when the state metric values for all of the states exceed a threshold value.

A Viterbi decoder configured to implement the rescaling technique may include a state metric register that stores the state metric values of each state and a controller that includes digital logic, such as an AND gate, to monitor bits output by the state metric registers to determine when the state metric values exceed the threshold value.

For instance, the controller may apply a most significant bit (MSB) of the state metric values from each of the state metric registers to multiple inputs of an AND gate. The output of the AND gate will be a ‘0’ when at least one of the MSBs of the state metric registers is not set, i.e., is not a ‘1’. However, the output of the AND gate will become a ‘1’ when the MSB of all of the state metric registers are set. Of course, the controller may rely on inverted logic to the same effect.

When the MSBs of all of the state metric registers become ‘1s,’ each of the state registers is at least half way to the maximum state metric value, i.e., the value at which overflow occurs. When the state metric values exceed the threshold value, the state metric values can be rescaled to avoid overflow. For example, the MSB of each state metric register can be reset when the state metric values exceed the threshold value.

In particular, when the output of the AND gate is ‘1,’ the MSB for each of the state metric registers is reset to ‘0.’ Resetting the MSB to ‘0’ is equivalent to subtracting half of the maximum value of the state metric register. For example, in the case of a 10-bit register, resetting the MSB of the state metric registers is equivalent to subtracting 512 from the state metric values of each state.

In one embodiment, the invention provides a method comprising computing state metric values for states of a decoder, and rescaling the state metric values when the state metric values exceed a threshold value.

In another embodiment, the invention provides a device comprising a state metric unit that computes state metric values for states of a decoder, and a control unit that determines when all of the state metric values have exceeded a threshold value, and reduces the state metric value associated with each of the states in response to the determination.

In a further embodiment, the invention provides a method comprising storing state metric values associated with decoder states in state metric registers, monitoring a bit of each of the state metric registers to determine when the state metric values exceed a threshold value, and resetting the bit of each of the state metric registers when state metric values exceed the threshold value.

The invention may provide one or more advantages. In general, the invention can provide a simplified technique for rescaling state metric values to avoid overflow. For example, in some embodiments, resetting a bit within the state metric register eliminates the need for subtractors to reduce the size of the state metric values, achieving reduced complexity and area. Further, resetting the bit of the state metric register when the state metric values exceed a threshold value allows the rescaling to be achieved without determination of a normalizing constant. In this case, rescaling can be accomplished by resetting the most significant bit or by subtractors, although resetting the most significant bit may be preferred for reduced complexity. The techniques described herein can reduce both the complexity of the rescaling implementation and latency. Reduced latency may be particularly desirable in wireless networking applications. Wireless networks conforming to the 802.11 a standard, for example, may benefit from reduced latency in processing state metric values for packet setup information, e.g., in the SIGNAL field.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a block diagram illustrating a wireless communication network.

FIG. 2 is a block diagram illustrating a wireless communication device in further detail.

FIG. 3 is a block diagram illustrating radio and modem circuitry within a wireless communication device for demodulation of an inbound (radio frequency) RF signal.

FIG. 4 is a block diagram illustrating an exemplary embodiment of a Viterbi decoder in accordance with the invention.

FIG. 5 is a block diagram illustrating an exemplary embodiment of a 4-state Viterbi decoder in accordance with the invention.

FIG. 6 is a block diagram illustrating an exemplary embodiment of an Add/Compare/Select (ACS) unit in accordance with the invention.

FIG. 7 is a flow diagram illustrating an exemplary mode of operation of a Viterbi decoder configured to rescale state metric values for overflow prevention.

### DETAILED DESCRIPTION

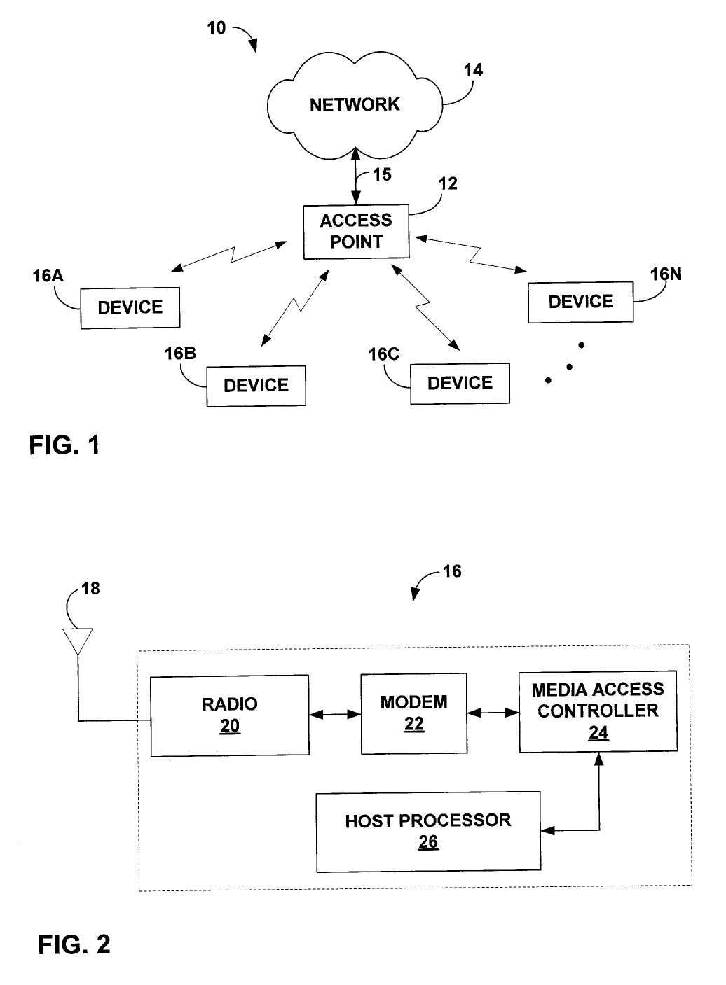

FIG. 1 is a block diagram illustrating a wireless communication network 10. Wireless communication network 10 includes at least one wireless access point 12 coupled to a wired network 14 via a link 15. Wireless access point 12 permits wireless communication between wired network 14 and one or more wireless communication devices 16A- 16N (“wireless communication devices 16”). Wireless access point 12 may integrate a hub, a switch or a router (not shown) to serve multiple wireless communication devices 16. Wireless communication network 10 may be used to communicate data, voice, video and the like between devices 16 and network 14 according to a variety of different wireless transmission techniques, such as Orthogonal Frequency Division Multiplexing (OFDM). Network 14 may be a local area network (LAN), wide area network (WAN) or global network such as the Internet. Link 15 may be an Ethernet or other network connection.

As will be described, wireless access point 12, wireless communication devices 16, or both may be configured to decode received symbols in accordance with the invention. In particular, wireless access point 12 and wireless communication devices 16 may be configured to track state metric values for each possible state of a decoder, and reduce the state metric values for the states when all of the state metric values exceed a threshold value. In this manner, the decoding techniques employed by wireless access point 12 and wireless communication devices 16 prevent state metric overflow while achieving reduced complexity and reduced latency.

FIG. 2 is a block diagram illustrating a wireless communication device 16 in further detail. Although certain embodiments of the invention will be described in the context of wireless communication device 16, the techniques described herein also may be implemented within other network devices such as wireless access point 12. Wireless communication device 16 includes a radio frequency (RF) antenna 18, radio circuitry 20, a modem 22, a media access controller (MAC) 24 and host processor 26. Wireless communication device 16 may take the form of a variety of wireless equipment, such as computers, personal computer cards, e.g., PCI or PCMCIA cards, personal digital assistants (PDAs), network audio or video appliances, and the like.

RF antenna 18 may receive and transmit RF signals between wireless communication device 16 and access point 12 within wireless communication network 10 (FIG. 1). Although FIG. 2 depicts the use of a single RF antenna 18, wireless communication device 16 may include more than one RF antenna 18. For example, wireless communication device 16 may include one RF antenna for receiving RF signals and another RF antenna for transmitting RF signals.

Radio circuitry 20 and modem 22 function together as a wireless transceiver. Radio 20 may include circuitry for upconverting transmitted signals to RF, and downconverting RF signals to baseband signals. In this sense, radio circuitry 20 may integrate both transmit and receive circuitry within a single transceiver component. In some cases, however, transmit and receive circuitry may be formed by separate transmitter and receiver components.

Modem 22 encodes information in a baseband signal for upconversion to the RF band by radio circuitry 20 and transmission via RF antenna 18. Similarly, modem 22 decodes information from RF signals received via antenna 18 and downconverted to baseband by radio circuitry 20. As will be described, modem 22 may include decoding circuitry that rescales state metric values during decoding to prevent state metric overflow. In particular, the decoding circuitry may be configured to reduce state metric values when the state metric values associated with the decoder states exceed a threshold value.

MAC 24 interacts with host processor 26 to facilitate communication between modem 22 and wireless communication device 16, e.g., a computer, PDA or the like. Hence, host processor 26 may be a central processing unit (CPU) within a computer or some other device. Radio circuitry 20, modem 22 and MAC 24 may be integrated on a common integrated circuit chip, or realized by discrete components.

Wireless communication network 10 (FIG. 1), access point 12 and wireless communication device 16 (FIG. 2) may conform to a variety of wireless networking standards, such as the IEEE 802.11a standard. The IEEE 802.11a standard, in particular, specifies a format for radio frequency (RF) transmission of orthogonal frequency division multiplexed (OFDM) data. The OFDM symbols transmitted according to the IEEE 802.11a standard occupy a 20 MHz bandwidth, which is divided into 64 equally spaced frequency bands.

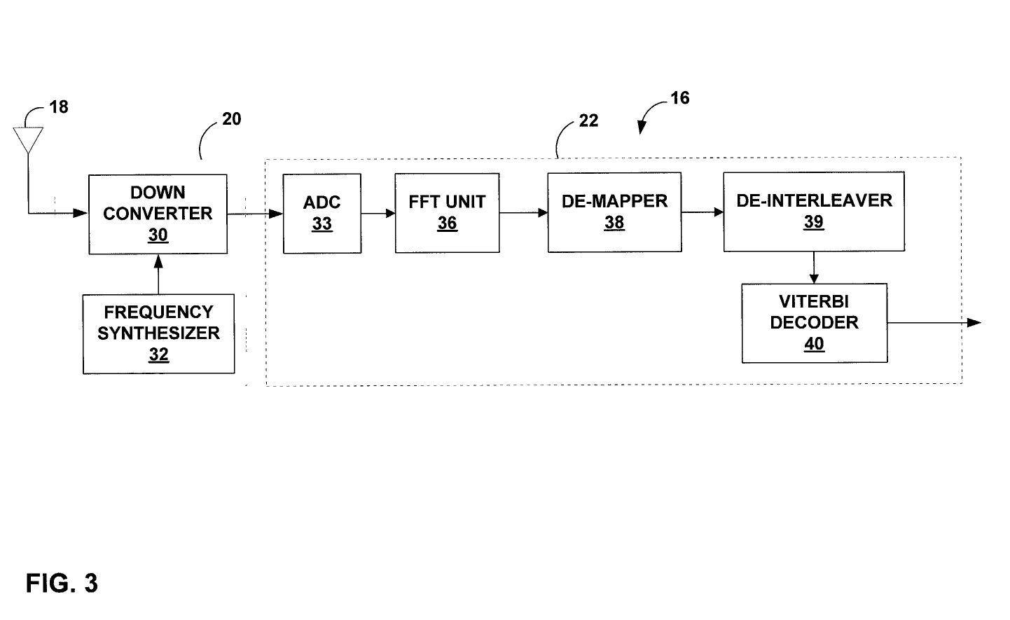

FIG. 3 is a block diagram illustrating radio and modem circuitry within a wireless communication device 16 for demodulation of an inbound RF signal. Similar radio and modem circuitry may be implemented in wireless access point 12. As shown in FIG. 3, radio circuitry 20 may include a downconverter 30 that receives an RF signal via RF antenna 18. Downconverter 30 mixes the received RF signal with a signal received from a frequency synthesizer 32 to convert the RF signal down to a baseband frequency. Radio circuitry 20 also may include a low noise amplifier and other signal conditioning circuitry (not shown).

As further shown in FIG. 3, modem 22 may include an analog-to-digital converter (ADC) 33 that produces a digital representation of the baseband signal. ADC 33 also may include an amplifier (not shown) that applies a gain to the analog baseband signal prior to conversion to a digital signal.

An FFT unit 36 processes the digital signal to produce FFT outputs and demodulates the signal. A signal de-mapper 38 uses a predetermined constellation to translate complex values obtained from the signal to phase and amplitude information for a subchannel on which the signal was received. The signal passes through a de-interleaver 39 before a convolutional decoder, such as Viterbi decoder 40, decodes the information carried by the received signal. For example, Viterbi decoder 40 decodes the information carried by a given tone and produces a stream of serial data for transmission to host processor 26 via MAC 24 (FIG. 2). As described in detail below, Viterbi decoder 40 tracks state metric values for possible states of a decoder, and rescales the state metric values for the possible states in order to prevent state metric overflow.

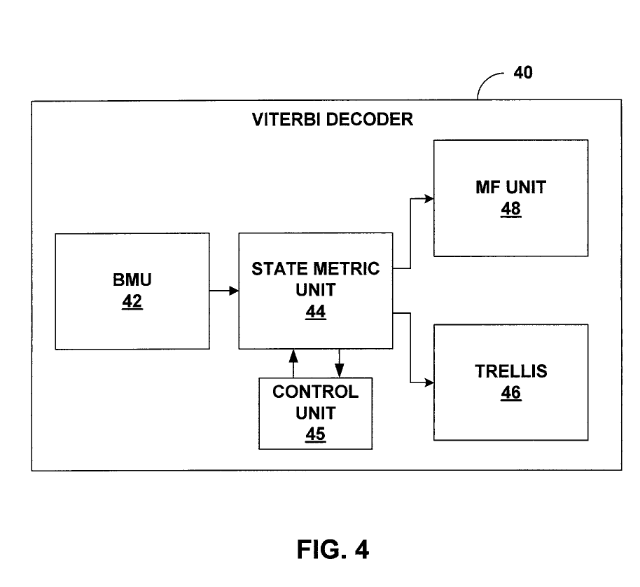

FIG. 4 is a block diagram illustrating an exemplary embodiment of a Viterbi decoder 40 in accordance with the invention. Viterbi decoder 40 includes a branch metric unit (BMU) 42 that receives input values, and computes branch metric values for branches emanating from the current state of the decoder. The input values may be probability values such as log likelihood ratio (LLR) values. Viterbi decoder 40 may compute the branch metric values using Hamming distances, Euclidean distances, and the like. Viterbi decoder 40 forwards the branch metric values calculated by BMU 42 to state metrics unit 44.

State metric unit 44 tracks the state metric values of the possible states of Viterbi decoder 40. More particularly, state metric unit 44 receives the branch metric values from BMU 42, and adds the branch metric values with associated state metric values to obtain updated state metric values. A portion of the updated state metric values may be applied to a minimum finder (MF) unit 48. MF unit 48 identifies the state with the minimum state metric value in order to determine a decoding index. State metric unit 44 further generates a decision bit, which is input to a trellis 46. The decision bits generated by state metric unit 44 determine the path taken through trellis 46. Viterbi decoder 40 uses the identified path through the trellis and the decoding index to output the decoded bit.

A controller 45 determines whether each of the updated state metric values exceeds a threshold value. If so, controller 45 rescales each of the state metric values to avoid state metric overflow. Controller 45 may rescale the state metric values, for example, by resetting a bit of each state metric value. Advantageously, the state metric values for the states of Viterbi decoder 40 have been observed to grow at the nearly the same rate. It has been mathematically proven, as documented in references such as A. P. Hekstra, “An alternative to Metric resealing in Viterbi Decoders”, IEEE Trans. Comm., Vol. 37, no. 11, pp. 1220-1222, November 1989, that the absolute difference between state metric values of any two states is upper bounded by the absolute value of the maximum branch metric. Consequently, the state metric values for the states are in the vicinity of each other. This is advantageous for operation of the techniques described herein. Specifically, the state metric values for the states pass the threshold value at substantially the same time and, moreover, without any of the states experiencing state metric overflow. Accordingly, comparison of the MSB of the states to the threshold value is effective in anticipating state metric overflow.

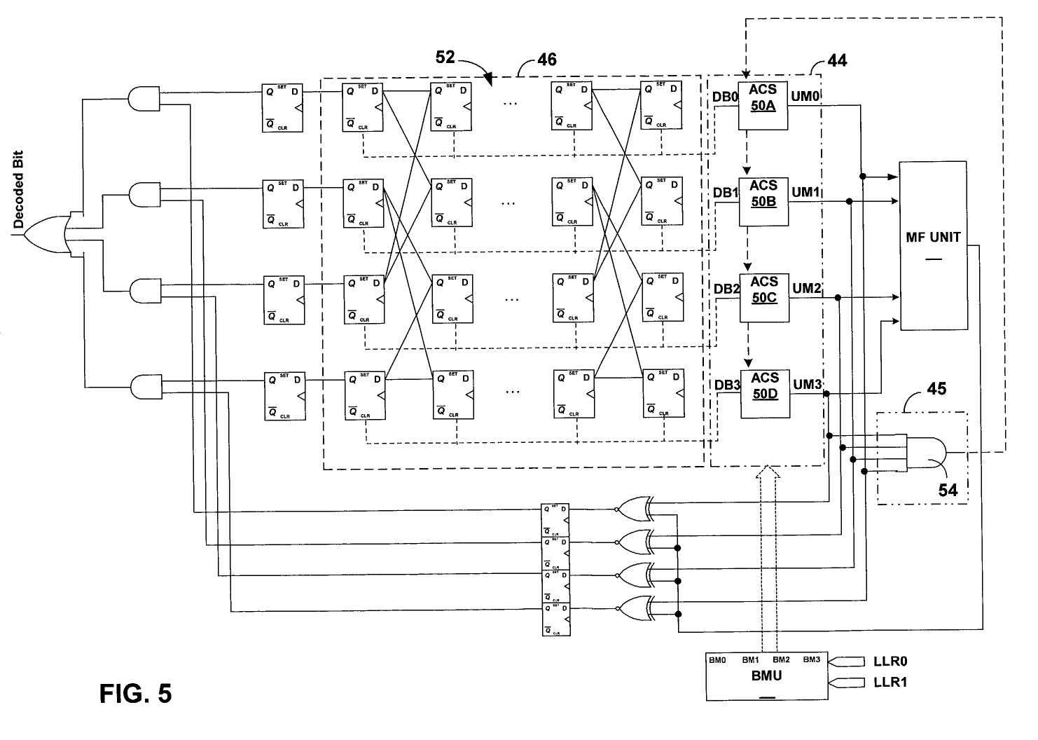

FIG. 5 is a block diagram illustrating an exemplary embodiment of a 4-state Viterbi decoder 40 in accordance with the invention. As shown in FIG. 5, Viterbi decoder 40 includes a BMU 42 that computes branch metric values for branches emanating from the current state of the decoder. More particularly, BMU 42 receives quantized input values, such as log likelihood ratios (LLRs), and generates branch metric values for each branch. In the example of FIG. 5, BMU 42 receives LLR0 and LLR1 and computes four branch metric values BM0-BM3. BMU 42 forwards branch metric values BM0-BM3 to state metric unit 44.

State metric unit 44 includes Add/Compare/Select units 50A-50D (ACS units 50). ACS units 50 compare and select one of the two branches that lead into a state. In particular, ACS units 50 add the branch metric value associated with each incoming branch to the cumulative sum of state metric values for the state from which each branch emanates to obtain updated state metric values. ACS units 50 compare the updated state metric values, and select the updated state metric value with the least metric value as a survivor state metric. ACS units 50 each store an associated survivor state metric value, and output the survivor state metric value, along with a decision bit. In the example of FIG. 5, each of ACS units 50 generate updated state metric values UM0-UM3 and decision bits DB0-DB3.

In accordance with the invention, Viterbi decoder 40 rescales the state metric values during decoding to prevent state metric overflow. More specifically, controller 45 determines whether each of the updated state metric values UM0-UM3 exceeds a threshold value, at which time controller 45 generates a control signal to reduce each of the state metric values. In the example of FIG. 5, controller 45 includes an AND gate 54 to compare a bit from the state metric registers (not shown) associated with each state to determine whether all of the state metric values exceed the defined value. For example, controller 45 may input the MSB of each state metric register into AND gate 54. The output of AND gate 54 may be connected to the Reset pin of the MSB of the state metric registers of ACS units 50. Upon the MSB of each state metric equaling ‘1,’ as determined by AND gate 54, controller 45 resets each MSB. In this manner, controller 45 serves to rescale each of the state metric values by a value equivalent to the MSB.

For instance, if the state metric registers were 10-bit registers, resetting the MSB would reduce the state metric value by 512. Advantageously, the resetting of the MSB to rescale the state metric values may take the place of subtracting. In addition, there is no need for Viterbi decoder 40 to find the minimum state metric value. Instead, upon detecting that all of the state metric values have exceeded the threshold value, controller 45 may reduce the state metric values by simply subtracting a constant value that is less than or equal to the monitored bit. In the case of subtraction, there is no need for Viterbi decoder 40 to find the minimum state metric value. Although controller 45 of FIG. 5 uses an AND gate 54 to compare the MSB of each state metric register to a threshold value, a variety of digital logic may be used to realize the approximate functionality of the AND gate. Also, in some embodiments, controller 45 may be configured to monitor and reset a bit other than the MSB.

As further shown in FIG. 5, Viterbi decoder 40 includes a trellis 46 of flip-flops 52. Trellis 46 includes a row of flip-flops 52 for each state of the decoder. Each row of flip-flops 52 of trellis 46 inputs the decision bit (DB) generated by ACS unit 50 associated with the row of flip-flops. The decision bit acts as a select bit for the value of the next state. In this manner, the decoder changes states as it traverses through the trellis. The number of flip-flops 52 in each row depends on a truncation length of the path. Although trellis 46 of FIG. 5 is constructed using D flip-flops, other type of flip-flops may be used, such as JK-flip flops, SR flip-flops, and the like. Further, other logic may be used to realize the approximate functionality of trellis 46. All flip-flops 52 of trellis 46 along with ACS units 50 can be connected to a common system clock.

Viterbi decoder 40 may further include an MF unit 48. MF unit 48 inputs updated state metric values UM0-UM3 generated by state metric unit 44, and compares the state metric values of the states to identify the state with the minimum state metric value in order to determine a decoding index. MF unit 48 may, for example, compare the state metric values of the states using a bank of comparators (not shown). To reduce the complexity of MF unit 48, MF unit 48 may ignore one or more of the least significant bits (LSBs) of the state metric values. Further, the comparators of MF unit 48 may be arranged in a tree-structure to reduce the latency associated with the comparisons. For example, for sixty-four state and 10-bit state metrics, a Viterbi decoder may have a six level tree of comparators where the first level includes 32 comparators, the second level includes 16 comparators, the third level includes 8 comparators, the fourth level includes 4 comparators, the fifth level includes 2 comparators, and the sixth level includes a single comparator. Viterbi decoder 40 outputs the next decoded bit using the decoding index identified by MF unit 48, and the last column of trellis 46. In some embodiments, Viterbi decoder 40 need not include an MF unit 48, but instead, may increase the number of flip-flops 52 in each trellis row. Accordingly, MF unit 48 is effective in reducing the number of flip-flops 52 in trellis 46, i.e., the truncation length, and, in turn, increasing performance of Viterbi decoder 40. For applications in which truncation length is less of a concern, Viterbi decoder 40 may dispense with inclusion of MF unit 48. In other words, MF unit 48 may be a desirable feature for enhanced performance, but is not generally necessary to operation of the rescaling techniques.

Although Viterbi decoder 40 described above only has four states for purposes of illustration, the principles of the invention may be applied to a Viterbi decoder with any number of states. In accordance with the 802.11a standard, for example, Viterbi decoder may comprise sixty-four states. In this case, controller 45 could implement a 64-input AND gate to monitor bits associated with the state metric values. In order to reduce latency, however, controller 45 could implement a bank of AND gates in the same manner as the bank of comparators of MF unit 48.

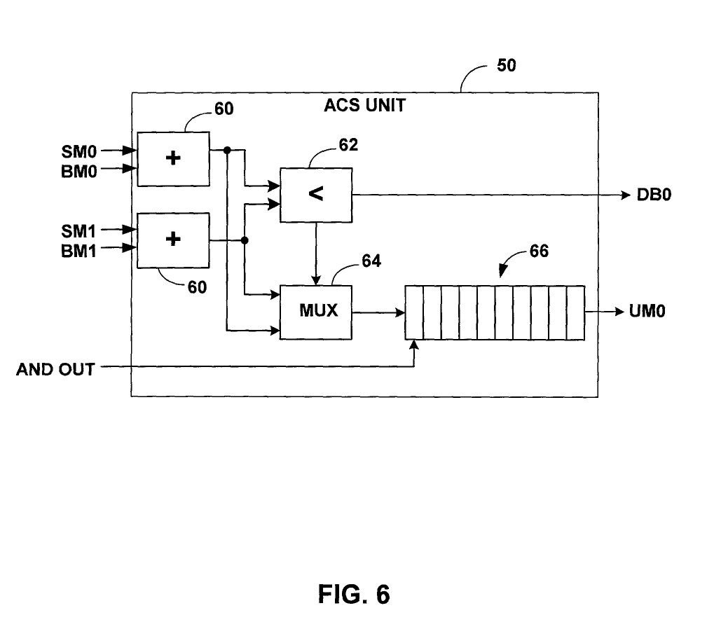

FIG. 6 is a block diagram illustrating an exemplary embodiment of an ACS unit 50 in accordance with the invention. In the example of FIG. 6, ACS unit 50 includes two adders 60, a comparator 62, a multiplexer 64, and a state metric register 66. In the example of FIG. 6, ACS 50 receives two branch metric values BM0 and BM1 from branch metric unit 42. ACS unit 50 further receives two state metric values SM0 and SM1. ACS unit 50 and another ACS unit generate state metric values SM0 and SM1 during the previous clock cycle. The state metric values may be stored in ACS unit 50 from computation of the previous clock cycle. Alternatively, ACS unit 50 may have a feedback loop that inputs the generated output.

ACS 50 sums the branch metric values and state metric values to obtain updated state metric values. For instance, ACS 50 and, more particularly, adders 60 sum BM0 and SM0, and sum BM1 and SM1 to obtain two updated state metric values. The updated state metric values are output to comparator 62 and multiplexer 64. Comparator 62 compares the updated state metric values and selects the state with the lowest state metric value. Multiplexer 64 selects one of the two state metrics using the value generated by comparator 62 as a select input. ACS unit 50 stores the state metric value selected by multiplexer 64 in state metric register 66. In the example of FIG. 6, the state metric register is a 10-bit register. However, the bit length of the register will depend on the number of bits of the state metric values.

The Reset pin of the most significant bit (MSB) of state metric register 66 is connected to the output of the AND gate, which performs an AND function on the MSBs of state metric register 66 of ACS units 50. When the output of the AND gate is a ‘0,’ the state metric values stored in state metric register 66 continue to increase. When the result of the AND gate is a ‘1,’ the state metric values stored in state metric register 66 of ACS units 50 are resealed by resetting the MSB and, in turn, subtracting an associated value from the state metric value. In this manner, there is no need for subtractors, providing reduced latency and reduced complexity. In some embodiments, subtractors could be used for rescaling upon determination that the MSB for all states have exceeded the threshold value. In other words, resetting the MSB is not the only way in which rescaling could be accomplished. In each case, however, rescaling can be performed in response to the MSB for all states exceeding the threshold value.

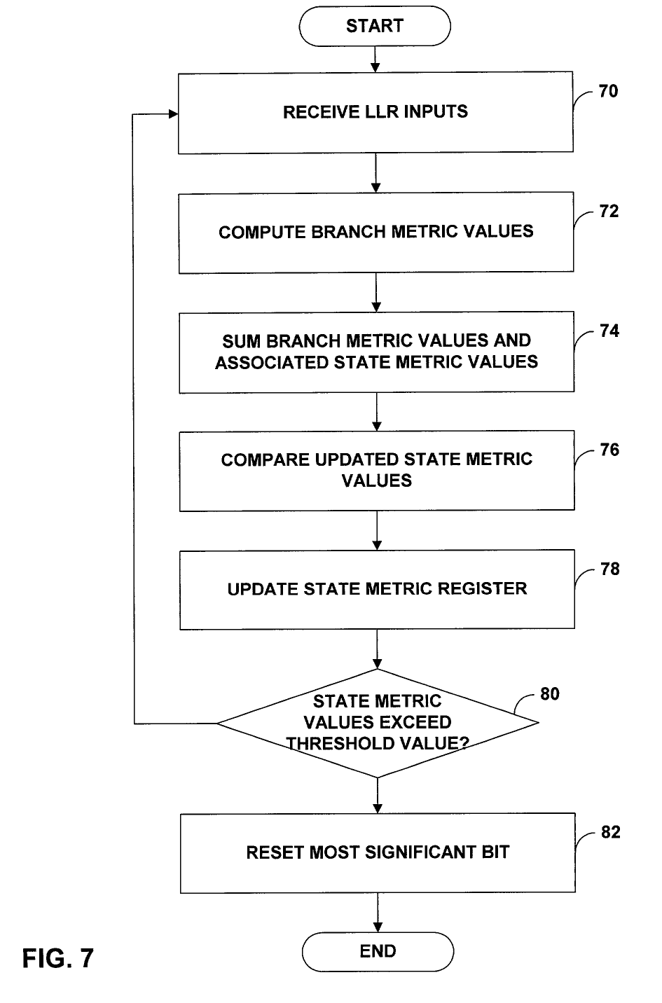

FIG. 7 is a flow diagram illustrating an exemplary mode of operation of a Viterbi decoder 40 configured to rescale state metric values as described herein. BMU 42 of Viterbi decoder 40 receives input, such as log likelihood ratios (LLRs) (70). BMU 42 computes branch metric values for each branch emanating from the current state of the decoder (72). For instance, Viterbi decoder 40 may compute the branch metric values using Hamming distances, Euclidean distances, or the like. ACS units 50 receive branch metric values from BMU 42, and add the branch metric values with current state metric values to obtain updated state metric values (74). Each ACS unit 50 compares the updated state metric values, and updates the state metric value maintained in state metric register 66 with the lowest of the state metric values (76, 78).

Controller 45 monitors the MSB of each state metric register 66 to determine when the state metric values of each state have exceeded a threshold value (80). For example, controller 45 may include a logic gate, such as AND gate 54, for monitoring the MSB of each state metric register 66. The threshold value may be a value associated with the MSB. For example, for a 10-bit register, the MSB may correspond to 512, in which case exceeding the threshold value includes exceeding a state metric value of 512. In other embodiments, the controller 45 may monitor a bit other than the most significant bit. Further, the controller 45 may monitor a combination of bits.

When the state metric values for all of the states exceed the threshold value, the output of the AND gate is ‘1,’ which results in a resetting of the MSB of state metric registers 66 (82). Resetting the MSB of state metric registers 66 is equivalent to reducing the state metric values by subtraction. For example, resetting the MSB of a 10-bit state metric register 66 is equivalent to subtracting 512 from the state metric value. In this manner, the rescaling technique is effective in preventing state metric value overflow, while offering reduced complexity and latency.

The rescaling techniques described herein can provide a simplified technique for resealing state metric values to avoid overflow. For example, resetting a bit within a state metric register eliminates the need for subtractors to reduce the size of the state metric values, achieving reduced complexity and area. In addition, resetting the bit of the state metric register when the state metric values exceed a threshold value allows the rescaling to be achieved without determination of a normalizing constant. This reduces the complexity of the rescaling implementation and reduces latency.

Reduced latency may be particularly desirable in wireless networking applications. Wireless networks conforming to the 802.11a standard, for example, may benefit from reduced latency in processing state metric values for packet setup information, e.g., in the SIGNAL field. In other words, the SIGNAL part of an 802.11a packet must be decoded very quickly because demodulating the remainder of the packet depends on the information contained in the SIGNAL part. State metric values for the Viterbi algorithm are initialized at the beginning of decoding an 802.11a packet. An 802.11a packet length can be up to 4093 bytes, however, causing the state metric values to grow substantially. To this end, the resealing technique provides a practical solution to the problem of state metric value overflow.

Various embodiments of the invention have been described. Note that the decoding techniques described herein may be useful in a variety of applications including wireless networking, wired networking and other applications in which Viterbi decoding is desirable. These and other embodiments are within the scope of the following claims.

1. A method comprising:
computing state metric values for states of a decoder; and
resealing the state metric values when the state metric values exceed a threshold value.

2. The method of claim 1, wherein rescaling the state metric values includes resetting bits in a register corresponding to the respective state metric values.

3. The method of claim 2, wherein resetting bits includes resetting the most significant bits (MSBs) of each of the registers.

4. The method of claim 1, wherein resealing the state metric values includes subtracting a constant from each of the state metric values.

5. The method of claim 1, further comprising monitoring a bit associated with each of the state metric values to determine when the state metric values exceed the threshold value.

6. The method of claim 5, wherein monitoring a bit includes monitoring the most significant bit associated with each of the state metric values.

7. The method of claim 5, wherein monitoring a bit includes applying a logic gate to the bits of the state metric values to determine when the bits associated with each of state metric values is a 1.

8. The method of claim 7, wherein applying a logic gate to the bits includes applying an AND gate to the bits.

9. The method of claim 1, further comprising identifying one of the state metric values having the smallest state metric value.

10. The method of claim 9, wherein identifying one of the state metric values having the smallest state metric value includes comparing the state metric values associated with each of the states.

11. The method of claim 10, wherein comparing the state metric values of each of the states includes comparing the state metric values of each of the states with one or more comparators.

12. The method of claim 9, further comprising outputting a decoded bit based on the state having the smallest state metric value.

13. A device comprising:
a state metric unit that computes state metric values for states of a decoder; and
a control unit that determines when all of the state metric values have exceeded a threshold value, and reduces the state metric value associated with each of the states in response to the determination.

14. The device of claim 13, wherein the state metric unit includes one or more add/compare/select (ACS) units.

15. The device of claim 14, wherein each of the ACS units includes:
a first adder that adds a first branch metric value to a first one of the state metric values to obtain a first updated state metric value;
a second adder that sums a second branch metric value with a second one of the state metric values to obtain a second updated state metric value;
a comparator that compares the first updated state metric value and the second updated state metric value; and
a multiplexer that selectively outputs one of the first and second updated state metric values having the lowest state metric value.

16. The device of claim 15, wherein the output generated by the comparator serves as a select bit for the multiplexer.

17. The device of claim 15, further comprising a state metric register that stores the state metric values output by the multiplexer.

18. The device of claim 17, wherein the control unit monitors a bit of the state metric register for each of the decoder states to determine when the state metric values associated with the states exceed the threshold value.

19. The device of claim 18, wherein the control unit resets the bit of the state metric register for each of the decoder states when the state metric values exceed the threshold value.

20. The device of claim 18, further comprising an AND gate that inputs the bit of the state metric register of each state, and determines when the state metric value of each state exceeds the defined value.

21. The device of claim 13, further comprising a minimum finder unit that identifies the state with the lowest state metric value.

22. The device of claim 13, further comprising a branch metric unit that computes the branch metric values.

23. The device of claim 13, wherein the device is a wireless communication device that communicates according to the IEEE 802.11a standard.

24. A method comprising:
storing state metric values associated with decoder states in state metric registers;
monitoring a bit of each of the state metric registers to determine when the state metric values exceed a threshold value; and
resetting the bit of each of the state metric registers when state metric values exceed the threshold value.

25. The method of claim 24, wherein the bit is the most significant bit.

26. The method of claim 24, further comprising updating the state metric values of the state metric registers.

27. The method of claim 24, wherein monitoring a bit of the state metric registers includes inputting the bit of each of the state metric registers into an AND gate.

28. The method of claim 24, further comprising:
identifying the state with the lowest state metric value; and
outputting a decoded bit from a trellis in accordance with the identified state.

29. The method of claim 24, further comprising using the state metric values for a Viterbi decoding process.
